(19) United States
(12) Patent Application Publication
(10) Pub. No.: US 2026/0042934 A1
(43) Pub. Date: Feb. 12, 2026

(54) COMPOSITIONS AND METHODS FOR POLISHING SUBSTRATES

(71) Applicant: ENTEGRIS, INC., Billerica, MA (US)

(72) Inventors: Aaron Walsh, Gainesville, FL (US); Aditya Dilip Verma, San Jose, CA (US); Sunny De, Oviedo, FL (US)

(21) Appl. No.: 19/293,844

(22) Filed: Aug. 7, 2025

Related U.S. Application Data
(60) Provisional application No. 63/680,524, filed on Aug. 7, 2024.

(51) Int. Cl. C09G 1/02; B24B 37/04; C09K 3/14; H01L 21/04; H01L 21/306

(52) U.S. Cl. CPC C09G 1/02; B24B 37/044; C09K 3/1436; H01L 21/0445; H01L 21/30625

(57) ABSTRACT

Compositions for polishing substrates are provided. A composition comprises at least one of a plurality of coated particles, an oxidizer, a pH adjuster, or any combination thereof. The plurality of coated particles, the oxidizer, and the pH adjuster are present in an amount sufficient for the composition, when used for polishing a silicon carbide substrate, to reduce a surface roughness, Rₐ, of the silicon carbide substrate to 0.1 nm or less; and/or remove silicon carbide from the silicon carbide substrate at a material removal rate of 0.01 μm/hr or greater. Related methods and related kits, among other things, are also provided.

### FIELD

The present disclosure relates to compositions and methods for polishing substrates.

### BACKGROUND

Chemical mechanical polishing is a process of smoothing surfaces with the combination of chemical and mechanical forces.

### SUMMARY

Some embodiments relate to a composition. In some embodiments, the composition comprises a plurality of coated particles. In some embodiments, the composition comprises an oxidizer. In some embodiments, the composition comprises a pH adjuster. In some embodiments, the plurality of coated particles, the oxidizer, and the pH adjuster are present in an amount sufficient for the composition, when used for polishing a silicon carbide substrate, to A) reduce a surface roughness, Rₐ, of the silicon carbide substrate to 0.1 nm or less; and/or B) remove silicon carbide from the silicon carbide substrate at a material removal rate of 0.01 μm/hr or greater.

Some embodiments relate to a method. In some embodiments, the method comprises obtaining a composition. In some embodiments, the composition comprises a plurality of coated particles. In some embodiments, the composition comprises an oxidizer. In some embodiments, the composition comprises a pH adjuster. In some embodiments, the method comprises dispensing the composition onto a silicon carbide substrate. In some embodiments, the method comprises polishing, with a pad, a surface of the silicon carbide substrate, with the composition located between the pad and the surface of the silicon carbide substrate, so as to: A) reduce a surface roughness, Rₐ, of the silicon carbide substrate to 0.1 nm or less; and/or B) remove silicon carbide from the silicon carbide substrate at a material removal rate of 0.01 μm/hr or greater.

Some embodiments relate to a kit. In some embodiments, the kit comprises a polishing pad. In some embodiments, the kit comprises a composition. In some embodiments, the composition comprises a plurality of coated particles. In some embodiments, the composition comprises an oxidizer. In some embodiments, the composition comprises a pH adjuster. In some embodiments, when the composition is dispensed onto a silicon carbide substrate and when the polishing pad is used to polish the silicon carbide substrate, the composition A) reduces a surface roughness, Rₐ, of the silicon carbide substrate to 0.1 nm or less; and/or B) removes silicon carbide from the silicon carbide substrate at a material removal rate of 0.01 μm/hr or greater.

### BRIEF DESCRIPTION OF THE DRAWINGS

FIG. 1 is a flow diagram of a method for polishing silicon carbide, according to some embodiments.

### DETAILED DESCRIPTION

Among those benefits and improvements that have been disclosed, other objects and advantages of this disclosure will become apparent from the following description taken in conjunction with the accompanying FIGURES. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

The term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Power devices such as dielectric films in semiconductor integrated circuits, optoelectronic devices such as light emitting devices (LEDs) and lasers, microelectromechanical systems (MEMS) based devices, and bio-medical systems, undergo chemical mechanical planarization (CMP) polishing to achieve smooth surfaces when polishing a silicon carbide substrate used to build the power device. CMP polishing may not meet surface finish requirements. Embodiments provided herein overcome at least these challenges associated with the reduction of surface roughness and an increased material removal rate of silicon carbide from the silicon carbide substrate. Obtaining smooth silicon carbide surfaces may be achieved with a reduction of surface roughness of a silicon carbide substrate and an increase in the removal rate of silicon carbide from the silicon carbide substrate.

Some embodiments relate to compositions. The compositions may be useful for reducing a surface roughness of a substrate, such as, for example and without limitation, a silicon carbide substrate, on either a silicon face and/or a carbon face of the silicon carbide substrate, while also increasing a material removal rate. The compositions provide improved throughput for single wafer polishing, among other applications, without, for example, having to employ a batch polishing process with tens or hundreds of wafers. In some embodiments, the compositions comprise low concentrations of an oxidizer, with a plurality of coated particles (e.g., having a Mohs hardness of 6 or less, among other values). In some embodiments, the compositions are useful when employed with soft polishing pads. The compositions disclosed herein exhibit enhanced performance with respect to surface roughness and material removal rates, among other things, relative to conventional slurry compositions used for, for example and without limitation, polishing silicon carbide substrates, among other substrates. The compositions further provide tunability with respect to surface roughness, material removal rate, and face selectivity, among other things.

In some embodiments, the composition comprises a plurality of coated particles.

In some embodiments, the composition comprises 1% to 10% by weight of the plurality of coated particles on a total weight of the composition, or any range or subrange between 1% and 10%. For example, in some embodiments, the composition comprises 1% to 9%, 1% to 8%, 1% to 7%, 1% to 6%, 1% to 5%, 1% to 4%, 1% to 3%, 1% to 2%, 2% to 10%, 3% to 10%, 4% to 10%, 5% to 10%, 6% to 10%, 7% to 10%, 8% to 10%, or 9% to 10% by weight of the plurality of coated particles on the total weight of the composition.

In some embodiments, the plurality of coated particles comprises at least one of a metal oxide coating, a core particle, or any combination thereof. In some embodiments, the plurality of coated particles comprises a metal oxide coating on a core particle. In some embodiments, the metal oxide coating covers all or at least a portion of the core particle. In some embodiments, the metal oxide coating directly contacts the core particle.

In some embodiments, the metal oxide coating comprises at least one of an alkali metal, an alkaline earth metal, a transition metal, a post-transition metal, or any combination thereof. In some embodiments, the metal oxide coating comprises at least one of a lithium oxide, a sodium oxide, a potassium oxide, a rubidium oxide, a cesium oxide, a francium oxide, a beryllium oxide, a magnesium oxide, a calcium oxide, a strontium oxide, a barium oxide, a radium oxide, a scandium oxide, a titanium oxide, a vanadium oxide, a chromium oxide, a manganese oxide, an iron oxide, a cobalt oxide, a nickel oxide, a copper oxide, a zinc oxide, a yttrium oxide, a zirconium oxide, a niobium oxide, a molybdenum oxide, a technetium oxide, a ruthenium oxide, a rhodium oxide, a palladium oxide, a silver oxide, a cadmium oxide, a hafnium oxide, a tantalum oxide, a tungsten oxide, a rhenium oxide, an osmium oxide, an iridium oxide, a platinum oxide, a gold oxide, a mercury oxide, an aluminum oxide, a gallium oxide, an indium oxide, tin oxide, a thallium oxide, a lead oxide, a bismuth oxide, a polonium oxide, or any combination thereof. In some embodiments, the metal oxide coating comprises a transition metal, such as, for example and without limitation, a manganese oxide. In some embodiments, the metal oxide coating is provided in a form of a plurality of particles agglomerated or otherwise associated with the core particle.

In some embodiments, the core particle comprises a metal oxide. In some embodiments, the metal oxide is different from a metal oxide of the metal oxide coating. In some embodiments, the core particle comprises at least one of silica, alumina, titania, zirconia, ceria, germania, magnesia, or any combination thereof. In some embodiments, the core particle comprises a silica. In some embodiments, the core particle comprises an alumina. In some embodiments, the core particle comprises a titania. In some embodiments, the core particle comprises a zirconia. In some embodiments, the core particle comprises a ceria. In some embodiments, the core particle comprises a germania. In some embodiments, the core particle comprises a magnesia.

In some embodiments, the plurality of coated particles may have a Mohs hardness of less than 6. For example, in some embodiments, the plurality of particles may have a Mohs hardness of 1 to 6, or any range or subrange between 1 and 6. In some embodiments, the plurality of particles may have a Mohs hardness ranging from 1 to 5, 1 to 4, 1 to 3, or 1 to 2. In some embodiments, the plurality of particles may have a Mohs hardness ranging from 2 to 6, 3 to 6, 4 to 6, or 5 to 6.

In some embodiments, the metal oxide coating may have a Mohs hardness of less than 6. For example, in some embodiments, the metal oxide coating may have a Mohs hardness of 1 to 6, or any range or subrange between 1 and 6. In some embodiments, the metal oxide coating may have a Mohs hardness ranging from 1 to 5, 1 to 4, 1 to 3, or 1 to 2. In some embodiments, the metal oxide coating may have a Mohs hardness ranging from 2 to 6, 3 to 6, 4 to 6, or 5 to 6.

In some embodiments, the Mohs hardness of the metal oxide coating is different from the Mohs hardness of the core particle. In some embodiments, the Mohs hardness of the metal oxide coating is less than the Mohs hardness of the core particle.

In some embodiments, the plurality of coated particles has an average particle size of 20 nanometers (nm) to 500 nm, or any range or subrange between 20 nm and 500 nm. For example, in some embodiments, the plurality of coated particles has an average particle size of 50 nm to 450 nm, 100 nm to 400 nm, 150 nm to 350 nm, or 200 nm to 300 nm. In some embodiments, the plurality of coated particles has an average particle size of 20 nm to 450 nm, 20 nm to 400 nm, 20 nm to 350 nm, 20 nm to 300 nm, 20 nm to 250 nm, 20 nm to 200 nm, 20 nm to 150 nm, 20 nm to 100 nm, or 20 nm to 50 nm. In some embodiments, the plurality of coated particles has an average particle size of 50 nm to 500 nm, 100 nm to 500 nm, 150 nm to 500 nm, 200 nm to 500 nm, 250 nm to 500 nm, 300 nm to 500 nm, 350 nm to 500 nm, 400 nm to 500 nm, or 450 nm to 500 nm. In some embodiments, the metal oxide coating, when provided in the form of a plurality of particles agglomerated or otherwise associated with the core particle, have any one or more of the average particle sizes provided above, such as, for example and without limitation, an average particle size of 20 nm to 500 nm, or any range or subrange between 20 nm and 500 nm.

In some embodiments, the composition comprises an oxidizer.

In some embodiments, the composition comprises 0.01% to 2% by weight of the oxidizer based on a total weight of the composition, or any range or subrange between 0.01% and 2%. For example, in some embodiments, the composition comprises 0.1% to 2%, 0.2% to 2%, 0.3% to 2%, 0.4% to 2%, 0.5% to 2%, 0.6% to 2%, 0.7% to 2%, 0.8% to 2%, 0.9% to 2%, 1% to 2%, 1.1% to 2%, 1.2% to 2%, 1.3% to 2%, 1.4% to 2%, 1.5% to 2%, 1.6% to 2%, 1.7% to 2%, 1.8% to 2%, 1.9% to 2%, 0.01% to 1.9%, 0.01% to 1.8%, 0.01% to 1.7%, 0.01% to 1.6%, 0.01% to 1.5%, 0.01% to 1.4%, 0.01% to 1.3%, 0.01% to 1.2%, 0.01% to 1.1%, 0.01% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, 0.01% to 0.1%, 0.5% to 1.5%, 0.6% to 1.4%, or 0.7% to 1.3% by weight of the oxidizer based on the total weight of the composition.

In some embodiments, the oxidizer comprises at least one of a permanganate, a peroxide, or any combination thereof. In some embodiments, the oxidizer comprises a permanganate. In some embodiments, the oxidizer comprises a peroxide. In some embodiments, the oxidizer comprises at least one of hydrogen peroxide (H₂O₂), FeCl₃, FeF₃, Fe(NO₃)₃, Sr(NO₃)₂, CoF₃, MnF₃, oxone (2KHSO₅·KHSO₄·K₂SO₄), periodic acid, iodic acid, vanadium (V) oxide, vanadium (IV,V) oxide, ammonium vanadate, ammonium polyatomic salts (e.g., ammonium peroxomonosulfate, ammonium chlorite (NH₄ClO₂), ammonium chlorate (NH₄ClO₃), ammonium iodate (NH₄IO₃), ammonium nitrate (NH₄NO₃), ammonium perborate (NH₄BO₃), ammonium perchlorate (NH₄ClO₄), ammonium periodate (NH₄IO₄), ammonium persulfate ((NH₄)₂S₂O₈), ammonium hypochlorite (NH₄ClO)), ammonium tungstate ((NH₄)₁₀H₂(W₂O₇)), sodium polyatomic salts (e.g., sodium persulfate (Na₂S₂O₈), sodium hypochlorite (NaClO), sodium perborate), potassium polyatomic salts (e.g., potassium iodate (KIO₃), potassium permanganate (KMnO₄), potassium persulfate, nitric acid (HNO₃), potassium persulfate (K₂S₂O₈), potassium hypochlorite (KClO)), tetramethylammonium polyatomic salts (e.g., tetramethylammonium chlorite ((N(CH₃)₄)ClO₂), tetramethylammonium chlorate ((N(CH₃)₄)ClO₃), tetramethylammonium iodate ((N(CH₃)₄)IO₃), tetramethylammonium perborate ((N(CH₃)₄)BO₃), tetramethylammonium perchlorate ((N(CH₃)₄)ClO₄), tetramethylammonium periodate ((N(CH₃)₄)₁₀₄), tetramethylammonium persulfate ((N(CH₃)₄)S₂O₈)), tetrabutylammonium polyatomic salts (e.g., tetrabutylammonium peroxomonosulfate), peroxomonosulfuric acid, ferric nitrate (Fe(NO₃)₃), urea hydrogen peroxide ((CO(NH₂)₂)H₂O₂), peracetic acid (CH₃(CO)OOH), 1,4-benzoquinone, toluquinone, dimethyl-1,4-benzoquinone, chloranil, alloxan, N-methylmorpholine N-oxide, trimethylamine N-oxide, or any combination thereof. In some embodiments, when the oxidizer is a salt, the oxidizer can be hydrated or anhydrous.

In some embodiments, the oxidizer may control the face selectivity of the silicon carbide substrate. In some embodiments, the face selectivity is a silicon face of the silicon carbide substrate. In some embodiments, the face selectivity is a carbon face of the silicon carbide. In some embodiments, the weight percentage of the oxidizer in the composition may be minimized to reduce the surface roughness of silicon carbide substrate.

In some embodiments, the composition comprises a pH adjuster.

In some embodiments, the composition comprises 0.01% to 15% by weight of the pH adjuster based on the total weight of the composition, or any range or subrange between 0.01% and 15%. In some embodiments, the composition comprises 0.02% to 14%, 0.03% to 13%, 0.04% to 12%, 0.05% to 11%, 0.1% to 10%, 0.2% to 9%, 0.3% to 8%, 0.4% to 7%, 0.5% to 5%, 1% to 4%, or 2% to 3%. In some embodiments, the composition comprises 0.02% to 14%, 0.03% to 13%, 0.04% to 12%, 0.05% to 11%, 0.1% to 10%, 0.2% to 9%, 0.3% to 8%, 0.4% to 7%, 0.5% to 5%, 1% to 4%, or 2% to 3%. In some embodiments, the composition comprises 0.02% to 15%, 0.03% to 15%, 0.04% to 15%, 0.05% to 15%, 0.1% to 15%, 0.2% to 15%, 0.3% to 15%, 0.4% to 15%, 0.5% to 15%, 1% to 15%, 2% to 15%, 3% to 15%, 4% to 15%, 5% to 15%, 6% to 15%, 7% to 15%, 8% to 15%, 9% to 15%, 10% to 15%, 11% to 15%, 12% to 15%, 13% to 15%, or 14% to 15%. In some embodiments, the composition comprises 0.01% to 14%, 0.01% to 13%, 0.01% to 12%, 0.01% to 11%, 0.01% to 10%, 0.01% to 9%, 0.01% to 8%, 0.01% to 7%, 0.01% to 5%, 0.01% to 4%, 0.01% to 3%, 0.01% to 2%, 0.01% to 1%, 0.01% to 0.5%, 0.01% to 0.4%, 0.01% to 0.3%, 0.01% to 0.2%, 0.01% to 0.1%, 0.01% to 0.05%, 0.01% to 0.04%, 0.01% to 0.03%, or 0.01% to 0.02%.

In some embodiments, the composition comprises 0.01% to 2% by weight of the pH adjuster based on the total weight of the composition, or any range or subrange between 0.01% and 2%. In some embodiments, the composition comprises 0.1% to 2%, 0.2% to 2%, 0.3% to 2%, 0.4% to 2%, 0.5% to 2%, 0.6% to 2%, 0.7% to 2%, 0.8% to 2%, 0.9% to 2%, 1% to 2%, 1.1% to 2%, 1.2% to 2%, 1.3% to 2%, 1.4% to 2%, 1.5% to 2%, 1.6% to 2%, 1.7% to 2%, 1.8% to 2%, 1.9% to 2%, 0.01% to 1.9%, 0.01% to 1.8%, 0.01% to 1.7%, 0.01% to 1.6%, 0.01% to 1.5%, 0.01% to 1.4%, 0.01% to 1.3%, 0.01% to 1.2%, 0.01% to 1.1%, 0.01% to 1%, 0.01% to 0.9%, 0.01% to 0.8%, 0.01% to 0.7%, 0.01% to 0.6%, 0.01% to 0.5%, 0.01% to 0.4%, 0.01% to 0.3%, 0.01% to 0.2%, 0.01% to 0.1%, 0.5% to 1.5%, 0.6% to 1.4%, or 0.7% to 1.3% by weight of the pH adjuster based on the total weight of the composition.

The pH adjuster may comprise a compound for adjusting a pH of the composition to a pH of 4 to 14 at 25° C. and 1 atm. In some embodiments, the pH adjuster may increase the removal rate. In some embodiments, the pH adjuster comprises an inorganic acid. In some embodiments, the pH adjuster comprises a nitric acid salt. In some embodiments, the pH adjuster may be present in an amount sufficient to adjust a selectivity of the composition.

In some embodiments, the pH adjuster comprises at least one of nitric acid, potassium hydroxide (KOH), or any combination thereof. In some embodiments, the pH adjuster comprises nitric acid. In some embodiments, the pH adjuster comprises potassium hydroxide.

The plurality of coated particles, the oxidizer, and the pH adjuster may be present in an amount sufficient for the composition, when used for polishing a silicon carbide substrate, to reduce a surface roughness, Rₐ, of the silicon carbide substrate to 0.1 nm or less. In some embodiments, the plurality of coated particles, the oxidizer, and the pH adjuster may be present in an amount sufficient for the composition, when used for polishing a silicon carbide substrate, to reduce a surface roughness, Rₐ, of the silicon carbide substrate to 0.01 nm to 0.1 nm, or any range or subrange between 0.01 nm and 0.1 nm. In some embodiments, the plurality of coated particles, the oxidizer, and the pH adjuster may be present in an amount sufficient for the composition, when used for polishing a silicon carbide substrate, to reduce a surface roughness, Rₐ, of the silicon carbide substrate to 0.01 nm to 0.1 nm, 0.01 nm to 0.09 nm, 0.01 nm to 0.08 nm, 0.01 nm to 0.07 nm, 0.01 nm to 0.06 nm, 0.01 nm to 0.05 nm, 0.01 nm to 0.04 nm, 0.01 nm to 0.03 nm, 0.01 nm to 0.02 nm, 0.02 nm to 0.1 nm, 0.03 nm to 0.1 nm, 0.04 nm to 0.1 nm, 0.05 nm to 0.1 nm, 0.06 nm to 0.1 nm, 0.07 nm to 0.1 nm, 0.08 nm to 0.1 nm, or 0.09 nm to 0.1 nm.

The plurality of coated particles, the oxidizer, and the pH adjuster may be present in an amount sufficient for the composition, when used for polishing a silicon carbide substrate, to reduce a surface roughness, Rₐ, of the silicon face of the silicon carbide substrate to 0.1 nm or less. In some embodiments, the plurality of coated particles, the oxidizer, and the pH adjuster may be present in an amount sufficient for the composition, when used for polishing a silicon carbide substrate, to reduce a surface roughness, Rₐ, of the silicon face of the silicon carbide substrate to 0.01 nm to 0.1 nm, or any range or subrange between 0.01 nm and 0.1 nm. In some embodiments, the plurality of coated particles, the oxidizer, and the pH adjuster may be present in an amount sufficient for the composition, when used for polishing a silicon carbide substrate, to reduce a surface roughness, Rₐ, of the silicon face of the silicon carbide substrate to 0.01 nm to 0.1 nm, 0.01 nm to 0.09 nm, 0.01 nm to 0.08 nm, 0.01 nm to 0.07 nm, 0.01 nm to 0.06 nm, 0.01 nm to 0.05 nm, 0.01 nm to 0.04 nm, 0.01 nm to 0.03 nm, 0.01 nm to 0.02 nm, 0.02 nm to 0.1 nm, 0.03 nm to 0.1 nm, 0.04 nm to 0.1 nm, 0.05 nm to 0.1 nm, 0.06 nm to 0.1 nm, 0.07 nm to 0.1 nm, 0.08 nm to 0.1 nm, or 0.09 nm to 0.1 nm.

The plurality of coated particles, the oxidizer, and the pH adjuster may be present in an amount sufficient for the composition, when used for polishing a silicon carbide substrate, to reduce a surface roughness, Rₐ, of the carbon face of the silicon carbide substrate to 0.1 nm or less. In some embodiments, the plurality of coated particles, the oxidizer, and the pH adjuster may be present in an amount sufficient for the composition, when used for polishing a silicon carbide substrate, to reduce a surface roughness, Rₐ, of the carbon face of the silicon carbide substrate to 0.01 nm to 0.1 nm, or any range or subrange between 0.01 nm and 0.1 nm. In some embodiments, the plurality of coated particles, the oxidizer, and the pH adjuster may be present in an amount sufficient for the composition, when used for polishing a silicon carbide substrate, to reduce a surface roughness, Rₐ, of the carbon face of the silicon carbide substrate to 0.01 nm to 0.1 nm, 0.01 nm to 0.09 nm, 0.01 nm to 0.08 nm, 0.01 nm to 0.07 nm, 0.01 nm to 0.06 nm, 0.01 nm to 0.05 nm, 0.01 nm to 0.04 nm, 0.01 nm to 0.03 nm, 0.01 nm to 0.02 nm, 0.02 nm to 0.1 nm, 0.03 nm to 0.1 nm, 0.04 nm to 0.1 nm, 0.05 nm to 0.1 nm, 0.06 nm to 0.1 nm, 0.07 nm to 0.1 nm, 0.08 nm to 0.1 nm, or 0.09 nm to 0.1 nm.

The plurality of coated particles, the oxidizer, and the pH adjuster may be present in an amount sufficient for the composition, when used for polishing a silicon carbide substrate, to remove silicon carbide from the silicon carbide substrate at a material rate of 0.01 μm/hr or greater. For example, in some embodiments, the plurality of coated particles, the oxidizer, and the pH adjuster are present in an amount sufficient for the composition, when used for polishing a silicon carbide substrate, to remove silicon carbide from the silicon carbide substrate at a material rate of 0.01 μm/hr to 5 μm/hr, or any range or subrange between 0.01 μm/hr to 5 μm/hr. In some embodiments, the plurality of coated particles, the oxidizer, and the pH adjuster are present in an amount sufficient for the composition, when used for polishing a silicon carbide substrate, to remove silicon carbide from the silicon carbide substrate at a material rate of 0.01 μm/hr to 5 μm/hr, 0.01 μm/hr to 4 μm/hr, 0.01 μm/hr to 3 μm/hr, 0.01 μm/hr to 2 μm/hr, 0.01 μm/hr to 1 μm/hr, 0.01 μm/hr to 0.5 μm/hr, 0.01 μm/hr to 0.1 μm/hr, 0.5 μm/hr to 5 μm/hr, 1 μm/hr to 5 μm/hr, 2 μm/hr to 5 μm/hr, 3 μm/hr to 5 μm/hr, or 4 μm/hr to 5 μm/hr.

The plurality of coated particles, the oxidizer, and the pH adjuster may be present in an amount sufficient for the composition, when used for polishing a silicon carbide substrate, to polish the silicon face of the silicon carbide substrate at a material removal rate of 0.01 μm/hr to 2 μm/hr, or any range or subrange between 0.01 μm/hr and 2 μm/hr. In some embodiments, for example, plurality of coated particles, the oxidizer, and the pH adjuster may be present in an amount sufficient for the composition, when used for polishing a silicon carbide substrate, to polish the silicon face of the silicon carbide substrate at a material removal rate of 0.01 μm/hr to 2 μm/hr, 0.05 μm/hr to 2 μm/hr, 0.1 μm/hr to 2 μm/hr, 0.5 μm/hr to 2 μm/hr, 1 μm/hr to 2 μm/hr, 1.5 μm/hr to 2 μm/hr, 0.01 μm/hr to 1.5 μm/hr, 0.01 μm/hr to 1 μm/hr, 0.01 μm/hr to 0.5 μm/hr, 0.01 μm/hr to 0.1 μm/hr, or 0.01 μm/hr to 0.05 μm/hr.

The plurality of coated particles, the oxidizer, and the pH adjuster may be present in an amount sufficient for the composition, when used for polishing a silicon carbide substrate, to polish the carbon face of the silicon carbide substrate at a material removal rate of 1 μm/hr to 5 μm/hr, or any range or subrange between 1 μm/hr and 5 μm/hr. In some embodiments, for example, the plurality of coated particles, the oxidizer, and the pH adjuster may be present in an amount sufficient for the composition, when used for polishing a silicon carbide substrate, to polish the carbon face of the silicon carbide substrate at a material removal rate of 1 μm/hr to 5 μm/hr, 1 μm/hr to 4 μm/hr, 1 μm/hr to 3 μm/hr, 1 μm/hr to 2 μm/hr, 2 μm/hr to 5 μm/hr, 3 μm/hr to 5 μm/hr, or 4 μm/hr to 5 μm/hr.

In some embodiments, the composition has a pH at 25° C. and 1 atm of 4 to 14. In some embodiments, the composition may have a pH at 25° C. and 1 atm of 4 to 13, 4 to 12, 4 to 11, 4 to 10, 4 to 9, 4 to 8, 4 to 7, 4 to 6, 4 to 5, 5 to 14, 6 to 14, 7 to 14, 8 to 14, 9 to 14, 10 to 14, 11 to 14, 12 to 14, 13 to 14, 5 to 13, 6 to 12, 7 to 11, or 8 to 10.

In some embodiments, the composition has a pH at 25° C. and 1 atm of 8 to 10. In some embodiments, the composition may have a pH at 25° C. and 1 atm of 8 to 9.8, 8 to 9.6, 8 to 9.4, 8 to 9.2, 8 to 9, 8 to 8.8, 8 to 8.6, 8 to 8.4, 8 to 8.2, 8.2 to 10, 8.4 to 10, 8.6 to 10, 8.8 to 10, 9 to 10, 9.2 to 10, 9.4 to 10, 9.6 to 10, or 9.8 to 10.

In some embodiments, increasing the pH may decrease the oxidizer strength to provide more isotropic polishing. In some embodiments, as the pH increases and the weight percentage of the oxidizer increases, the surface roughness quality decreases.

In some embodiments, the composition comprises a surfactant.

The surfactant may repel each of the plurality of coated particles from one another to improve the composition stability. The surfactant may reduce the agglomeration of the plurality of coated particles.

In some embodiments, the composition comprises 0.001% to 0.1% by weight of the surfactant based on the total weight of the composition, or any range or subrange between 0.001% and 0.1%. In some embodiments, the composition comprises 0.001% to 0.009%, 0.001% to 0.008%, 0.001% to 0.007%, 0.001% to 0.006%, 0.001% to 0.005%, 0.001% to 0.004%, 0.001% to 0.003%, 0.001% to 0.002%, 0.002% to 0.01%, 0.003% to 0.01%, 0.004% to 0.01%, 0.005% to 0.01%, 0.006% to 0.01%, 0.007% to 0.01%, 0.008% to 0.01%, or 0.009% to 0.01%.

In some embodiments, the surfactant comprises at least one of a non-ionic surfactant, a cationic surfactant, an anionic surfactant, or any combination thereof. In some embodiments, the surfactant comprises a non-ionic surfactant. In some embodiments, the surfactant comprises a cationic surfactant. In some embodiments, the surfactant comprises an anionic surfactant.

In some embodiments, the non-ionic surfactant comprises at least one of polyethylene glycol ethers, polypropylene glycol alkyl ethers, glucoside alkyl ethers, polyethylene glycol octylphenyl ethers, polyethylene glycol alkylphenyl ethers, glycerol alkylesters, polyoxyehylene glycol sorbitan alkyl esters, sorbitan alkyl esters, cocamide, dodeceyldimethylamine oxide, block copolymers of polyethylene glycol and poly propylene glycol, polyethoxylated tallow amine, or any combination thereof.

In some embodiments, the cationic surfactant comprises at least one of cetrimonium bromide, cetyl ammonium bromide, or any combination thereof.

In some embodiments, the anionic surfactant comprises a secondary alkyl sulfonate (SAS). In some embodiments, the anionic surfactant comprises sodium dodecyl.

In some embodiments, the composition comprises a water. In some embodiments, the composition comprises 90% to 95% by weight of the water based on a total weight of the composition, or any range or subrange between 90% and 95%. In some embodiments, for example, the water by weight based on a total weight of the composition may be 91% to 94%, or 92% to 93%. In some embodiments, the water by weight based on a total weight of the composition may be 91% to 95%, 92% to 95%, 93% to 95%, or 94% to 95%. In some embodiments, the water by weight based on a total weight of the composition may be 90% to 94%, 90% to 93%, 90% to 92%, or 90% to 91%.

The silicon carbide on the surface of the silicon carbide substrate may be a polycrystalline hard material. The surface of the silicon carbide substrate may be of any crystalline orientation. In some embodiments, the crystalline orientation of the surface of the silicon carbide substrate may be a silicon face (Si-face), a carbon face (C-face), a mixed face, an m-face, an a-face, any miscut from regular crystallographic faces, any polytype, mixed polytype, doped, undoped, polycrystalline, amorphous, cubic or hexagonal symmetry. The silicon carbide surface may also be composed of materials in non-stochiometric amorphous can be materials in a dielectric form (such as carbon doped silicon oxide or carbon doped silicon nitride) used in low k (dielectric constant less than 4) applications with an overall composition of Six-Cy-Nz-Oa where x, y, can vary from 0.05 to 0.95, while z, a can vary from 0.00 to 0.90. The dielectric films can be used in formation of copper-based interconnects, metal gate electronics or generally any dielectric films application in the silicon-based semiconductor industry.

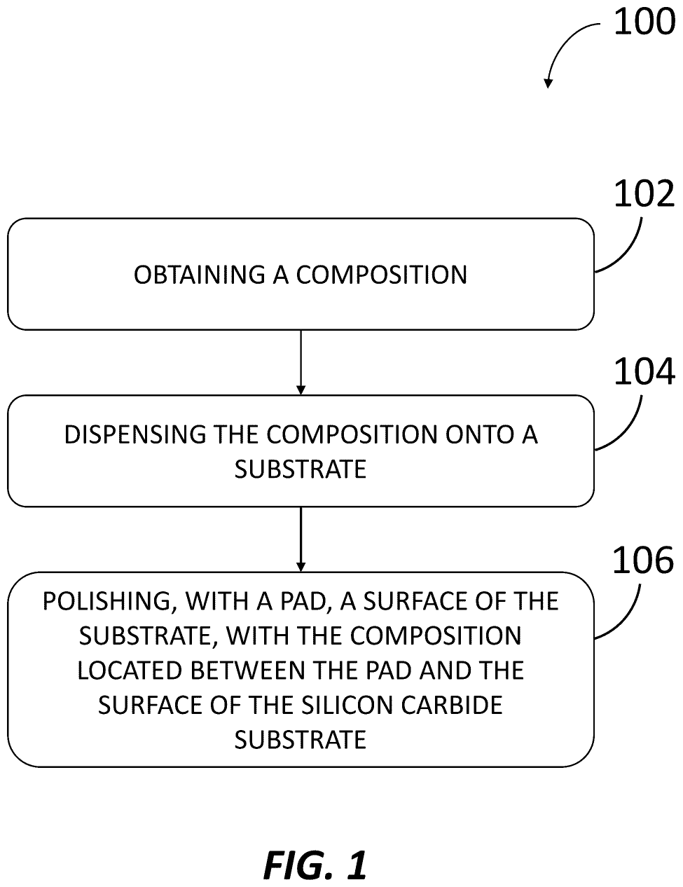

FIG. 1 is a flow diagram of a method for polishing a substrate, according to some embodiments. As shown in FIG. 1, in some embodiments, the method for polishing a substrate comprises one or more of the following steps: obtaining 102 a composition; dispensing 104 the composition onto a substrate; and polishing 106, with a pad, a surface of the substrate, with the composition located between the pad and the surface of the substrate.

At step 102, in some embodiments, the method for polishing a substrate comprises obtaining a composition. In some embodiments, the composition comprises a plurality of coated particles, an oxidizer, and a pH adjuster. It will be appreciated that the composition may comprise any one or more of the compositions disclosed herein, without departing from the scope of this disclosure.

At step 104, in some embodiments, the method for polishing a substrate comprises dispensing the composition onto a substrate. In some embodiments, the dispensing comprises applying the composition onto the substrate. In some embodiments, the dispensing comprises flowing the composition on the substrate. The substrate may comprise any one or more of the substrates disclosed herein. For example, in some embodiments, the substrate comprises a silicon carbide substrate.

At step 106, in some embodiments, the method for polishing a substrate comprises polishing, with a pad, a surface of the substrate, with the composition located between the pad and the surface of the substrate. In some embodiments, the polishing comprises rotating the pad with the composition located between the pad and the substrate. In some embodiments, the polishing comprises applying a force via the pad with the composition located between the pad and the substrate.

In some embodiments, the polishing reduces a surface roughness, Rₐ, of the silicon carbide substrate to 0.01 nm to 0.1 nm, or any range or subrange between 0.01 nm and 0.1 nm. In some embodiments, the polishing reduces a surface roughness, Rₐ, of the silicon carbide substrate to 0.01 nm to 0.1 nm, 0.01 nm to 0.09 nm, 0.01 nm to 0.08 nm, 0.01 nm to 0.07 nm, 0.01 nm to 0.06 nm, 0.01 nm to 0.05 nm, 0.01 nm to 0.04 nm, 0.01 nm to 0.03 nm, 0.01 nm to 0.02 nm, 0.02 nm to 0.1 nm, 0.03 nm to 0.1 nm, 0.04 nm to 0.1 nm, 0.05 nm to 0.1 nm, 0.06 nm to 0.1 nm, 0.07 nm to 0.1 nm, 0.08 nm to 0.1 nm, or 0.09 nm to 0.1 nm.

In some embodiments, the polishing removes silicon carbide from the silicon carbide substrate at a material removal rate of 0.01 μm/hr to 5 μm/hr, or any range or subrange between 0.01 μm/hr to 5 μm/hr. In some embodiments, the polishing removes silicon carbide from the silicon carbide substrate at a material removal rate of 0.01 μm/hr to 5 μm/hr, 0.01 μm/hr to 4 μm/hr, 0.01 μm/hr to 3 μm/hr, 0.01 μm/hr to 2 μm/hr, 0.01 μm/hr to 1 μm/hr, 0.01 μm/hr to 0.5 μm/hr, 0.01 μm/hr to 0.1 μm/hr, 0.5 μm/hr to 5 μm/hr, 1 μm/hr to 5 μm/hr, 2 μm/hr to 5 μm/hr, 3 μm/hr to 5 μm/hr, or 4 μm/hr to 5 μm/hr.

In some embodiments, the polishing polishes the silicon face of the silicon carbide substrate at a material removal rate of 0.01 μm/hr to 2 μm/hr, or any range or subrange between 0.01 μm/hr and 2 μm/hr. In some embodiments, for example, the polishing polishes the silicon face of the silicon carbide substrate at a material removal rate of 0.01 μm/hr to 2 μm/hr, 0.05 μm/hr to 2 μm/hr, 0.1 μm/hr to 2 μm/hr, 0.5 μm/hr to 2 μm/hr, 1 μm/hr to 2 μm/hr, 1.5 μm/hr to 2 μm/hr, 0.01 μm/hr to 1.5 μm/hr, 0.01 μm/hr to 1 μm/hr, 0.01 μm/hr to 0.5 μm/hr, 0.01 μm/hr to 0.1 μm/hr, or 0.01 μm/hr to 0.05 μm/hr.

In some embodiments, the polishing polishes the carbon face of the silicon carbide substrate at a material removal rate of 1 μm/hr to 5 μm/hr, or any range or subrange between 1 μm/hr and 5 μm/hr. In some embodiments, the polishing polishes the carbon face of the silicon carbide substrate at a material removal rate of 1 μm/hr to 5 μm/hr, 1 μm/hr to 4 μm/hr, 1 μm/hr to 3 μm/hr, 1 μm/hr to 2 μm/hr, 2 μm/hr to 5 μm/hr, 3 μm/hr to 5 μm/hr, or 4 μm/hr to 5 μm/hr.

The pad may comprise a woven pad and/or a non-woven pad. A pad may comprise a polymer of varying density, hardness, thickness, compressibility, have an ability to rebound upon compression, and compression modulus. In some embodiments, the polymer comprises at least one of polyvinylchloride, polyvinyl fluoride, nylon, fluorocarbon, polycarbonate, polyester, polyacrylate, polyether, polyethylene, polyamide, polyurethane, polystyrene, polypropylene, or any combination thereof. In some embodiments, the pad has a circular shape and, when in use, may have a rotational motion about an axis perpendicular to the plane defined by the surface of the pad. In some embodiments, the pad has a cylindrical shape, the surface of which acts as the polishing surface, and, when in use, may have a rotational motion about the central axis of the cylinder. In some embodiments, the pad is provided in a form of an endless belt, which, when in use, may have a linear motion with respect to the cutting edge being polished. In some embodiments, when in use, the pad has a reciprocating or orbital motion along a plane or a semicircle.

Some embodiments relate to a kit. The kit may comprise a polishing pad and a composition. It will be appreciated that any one or more of the pads and/or compositions disclosed herein may be employed, without departing from the scope of this disclosure. For example, in some embodiments, the composition comprises at least one of a plurality of coated particles, an oxidizer, a pH adjuster, or any combination thereof. In some embodiments, when the composition is dispensed onto a silicon carbide substrate and when the polishing pad is used to polish the silicon carbide substrate, the composition reduces a surface roughness, Rₐ, of the silicon carbide substrate to 0.1 nm or less; and/or B) removes silicon carbide from the silicon carbide substrate at a material removal rate of 0.01 μm/hr or greater.

Any one or more of the embodiments disclosed herein shall be understood to be combinable without departing from the scope or spirit of the disclosure.

### Example 1

Various compositions were prepared and the performance of each was evaluated. Table 1 provides the formulation details for each of the Samples A-E. Unless otherwise provided, all weight percentages are based on a total weight of each sample.

TABLE 1

| | Plurality | | KOH | | |
|---|---|---|---|---|---|
| | of Coated | KMnO₄ | (pH | SAS | Deionized |
| Sample | Particles | (Oxidizer) | Adjuster) | (Surfactant) | Water |
| A | 1% | 0.01% | 0.04% | 0.005% | Balance |
| B | 1% | 2% | 0.04% | 0.005% | Balance |
| C | 1% | 1% | 0.04% | 0.005% | Balance |
| D | 1% | 0.001% | 0.04% | 0.005% | Balance |
| E | 1% | 3% | 0.04% | 0.005% | Balance |

Table 2 provides the material removal rate (MRR) and surface roughness (Rₐ) values for each of the Samples A-F.

TABLE 2

| Sample | MRR (μm/hr) | Rₐ (nm) |
|---|---|---|
| A | 0.1 | 0.06 |
| B | 0.8 | 0.04 |
| C | 0.8 | 0.04 |
| D | 0.1 | 0.06 |
| E | 1.1 | 0.04 |

### Example 2

Various compositions were prepared and the performance of each was evaluated. Table 3 provides the formulation details for each of the samples.

TABLE 3

| | Plurality | KMnO₄ | | | SAS | |
|---|---|---|---|---|---|---|
| Sam- | of Coated | (Oxi- | pH | | (Surfac- | Deionized |
| ple | Particles | dizer) | Adjuster | pH | tant) | Water |
| F | 1% | 1% | 0.04% HNO₃ | 4 | 0.005% | Balance |
| G | 1% | 1% | 0.1% KOH | 12 | 0.005% | Balance |
| H | 1% | 1% | 0.04% KOH | 9-10 | 0.005% | Balance |
| I | 1% | 1% | 0.2% HNO₃ | 2 | 0.005% | Balance |
| J | 1% | 1% | 10% KOH | 14 | 0.005% | Balance |

Table 4 provides the material removal rate (MRR) and surface roughness (Rₐ) values for each of the samples.

TABLE 4

| Sample | MRR (μm/hr) | Rₐ (nm) |
|---|---|---|
| F | 2.4 | 0.07 |
| G | 0.4 | 0.06 |
| H | 0.8 | 0.04 |
| I | 12.9 | 0.2 |
| J | 0.8 | 0.07 |

### ASPECTS

Various Aspects are described below. It is to be understood that any one or more of the features recited in the following Aspect(s) can be combined with any one or more other Aspect(s).

Aspect 1. A composition comprising:
a plurality of coated particles;
an oxidizer; and
a pH adjuster;
   wherein the plurality of coated particles, the oxidizer, and the pH adjuster are present in an amount sufficient for the composition, when used for polishing a silicon carbide substrate, to:
      A) reduce a surface roughness, Rₐ, of the silicon carbide substrate to 0.1 nm or less; and
      B) remove silicon carbide from the silicon carbide substrate at a material removal rate of 0.01 μm/hr or greater.

Aspect 2. The composition according to Aspect 1, wherein the composition comprises 1% to 10% by weight of the plurality of coated particles based on a total weight of the composition.

Aspect 3. The composition according to any one of Aspects 1-2, wherein the composition comprises 0.01% to 2% by weight of the oxidizer based on a total weight of the composition.

Aspect 4. The composition according to any one of Aspects 1-3, wherein the composition comprises 0.5% to 1.5% by weight of the oxidizer based on a total weight of the composition.

Aspect 5. The composition according to any one of Aspects 1-4, wherein the composition comprises 0.01% to 15% by weight of the pH adjuster based on a total weight of the composition.

Aspect 6. The composition according to any one of Aspects 1-5, wherein the plurality of coated particles comprises a transition metal oxide coating on a core particle.

Aspect 7. The composition according to Aspect 6, wherein the transition metal oxide coating comprises a manganese oxide.

Aspect 8. The composition according to Aspect 6, wherein the core particle comprises at least one of silica, alumina, titania, zirconia, ceria, germania, magnesia, or any combination thereof.

Aspect 9. The composition according to any one of Aspects 1-8, wherein the oxidizer comprises at least one of a permanganate, a peroxide, or any combination thereof.

Aspect 10. The composition according to any one of Aspects 1-9, wherein the composition has a pH at 25° C. and 1 atm of 4 to 14.

Aspect 11. The composition according to any one of Aspects 1-10, further comprising:
a surfactant,
   wherein the surfactant comprises at least one of a non-ionic surfactant, a cationic surfactant, an anionic surfactant, or any combination thereof.

Aspect 12. A method comprising:
obtaining a composition,
   wherein the composition comprises:
      a plurality of coated particles;
      an oxidizer; and
      a pH adjuster;
dispensing the composition onto a silicon carbide substrate; and
polishing, with a pad, a surface of the silicon carbide substrate, with the composition located between the pad and the surface of the silicon carbide substrate, so as to:
   A) reduce a surface roughness, Rₐ, of the silicon carbide substrate to 0.1 nm or less; and
   B) remove silicon carbide from the silicon carbide substrate at a material removal rate of 0.01 μm/hr or greater.

Aspect 13. The composition according to Aspect 12, wherein the composition comprises 1% to 10% by weight of the plurality of coated particles based on a total weight of the composition.

Aspect 14. The composition according to any one of Aspects 12-13, wherein the composition comprises 0.01% to 2% by weight of the oxidizer based on a total weight of the composition.

Aspect 15. The composition according to any one of Aspects 12-14, wherein the composition comprises 0.01% to 15% by weight of the pH adjuster based on a total weight of the composition.

Aspect 16. The composition according to any one of Aspects 12-15, wherein the oxidizer comprises at least one of a permanganate, a peroxide, or any combination thereof.

Aspect 17. The composition according to any one of Aspects 12-16, wherein the composition has a pH at 25° C. and 1 atm of 4 to 14.

Aspect 18. The method according to any one of Aspects 12-17, wherein the polishing reduces the surface roughness, Rₐ, of the silicon carbide substrate to 0.01 nm to 0.1 nm.

Aspect 19. The method according to any one of Aspects 12-18, wherein the polishing removes silicon carbide from the silicon carbide substrate at a material removal rate of 0.01 μm/hr to 2 μm/hr.

Aspect 20. A kit comprising:
a polishing pad; and
a composition,
   wherein the composition comprises:
      a plurality of coated particles;
      an oxidizer; and
      a pH adjuster;
         wherein, when the composition is dispensed onto a silicon carbide substrate and when the polishing pad is used to polish the silicon carbide substrate, the composition:
         A) reduces a surface roughness, Rₐ, of the silicon carbide substrate to 0.1 nm or less; and
         ′B) removes silicon carbide from the silicon carbide substrate at a material removal rate of 0.01 μm/hr or greater.

What is claimed is:

1. A composition comprising:
a plurality of coated particles;
an oxidizer; and
a pH adjuster;
wherein the plurality of coated particles, the oxidizer, and the pH adjuster are present in an amount sufficient for the composition, when used for polishing a silicon carbide substrate, to:
A) reduce a surface roughness, Rₐ, of the silicon carbide substrate to 0.1 nm or less; and
B) remove silicon carbide from the silicon carbide substrate at a material removal rate of 0.01 μm/hr or greater.

2. The composition of claim 1, wherein the composition comprises 1% to 10% by weight of the plurality of coated particles based on a total weight of the composition.

3. The composition of claim 1, wherein the composition comprises 0.01% to 2% by weight of the oxidizer based on a total weight of the composition.

4. The composition of claim 1, wherein the composition comprises 0.5% to 1.5% by weight of the oxidizer based on a total weight of the composition.

5. The composition of claim 1, wherein the composition comprises 0.01% to 15% by weight of the pH adjuster based on a total weight of the composition.

6. The composition of claim 1, wherein the plurality of coated particles comprises a transition metal oxide coating on a core particle.

7. The composition of claim 6, wherein the transition metal oxide coating comprises a manganese oxide.

8. The composition of claim 6, wherein the core particle comprises at least one of silica, alumina, titania, zirconia, ceria, germania, magnesia, or any combination thereof.

9. The composition of claim 1, wherein the oxidizer comprises at least one of a permanganate, a peroxide, or any combination thereof.

10. The composition of claim 1, wherein the composition has a pH at 25° C. and 1 atm of 4 to 14.

11. The composition of claim 1, further comprising:
a surfactant,
wherein the surfactant comprises at least one of a non-ionic surfactant, a cationic surfactant, an anionic surfactant, or any combination thereof.

12. A method comprising:
obtaining a composition,
wherein the composition comprises:
a plurality of coated particles;
an oxidizer; and
a pH adjuster;
dispensing the composition onto a silicon carbide substrate; and
polishing, with a pad, a surface of the silicon carbide substrate, with the composition located between the pad and the surface of the silicon carbide substrate, so as to:
A) reduce a surface roughness, Rₐ, of the silicon carbide substrate to 0.1 nm or less; and
B) remove silicon carbide from the silicon carbide substrate at a material removal rate of 0.01 μm/hr or greater.

13. The method of claim 12, wherein the composition comprises 1% to 10% by weight of the plurality of coated particles based on a total weight of the composition.

14. The method of claim 12, wherein the composition comprises 0.01% to 2% by weight of the oxidizer based on a total weight of the composition.

15. The method of claim 12, wherein the composition comprises 0.01% to 15% by weight of the pH adjuster based on a total weight of the composition.

16. The method of claim 12, wherein the oxidizer comprises at least one of a permanganate, a peroxide, or any combination thereof.

17. The method of claim 12, wherein the composition has a pH at 25° C. and 1 atm of 4 to 14.

18. The method of claim 12, wherein the polishing reduces the surface roughness, Rₐ, of the silicon carbide substrate to 0.01 nm to 0.1 nm.

19. The method of claim 12, wherein the polishing removes silicon carbide from the silicon carbide substrate at a material removal rate of 0.01 μm/hr to 2 μm/hr.

20. A kit comprising:
a polishing pad; and
a composition,
wherein the composition comprises:
a plurality of coated particles;
an oxidizer; and
a pH adjuster;
wherein, when the composition is dispensed onto a silicon carbide substrate and when the polishing pad is used to polish the silicon carbide substrate, the composition:
′A) reduces a surface roughness, Rₐ, of the silicon carbide substrate to 0.1 nm or less; and
B) removes silicon carbide from the silicon carbide substrate at a material removal rate of 0.01 μm/hr or greater.
